(19) United States
(12) Patent Application Publication
(10) Pub. No.: US 2018/0359886 A1
(43) Pub. Date: Dec. 13, 2018

(54) METHODS OF MAKING INTERCONNECT SUBSTRATE HAVING STRESS MODULATOR AND CRACK INHIBITING LAYER AND MAKING FLIP CHIP ASSEMBLY THEREOF

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 16/046,243

(22) Filed: Jul. 26, 2018

Related U.S. Application Data
(63) Continuation-in-part of application No. 14/846,987, filed on Sep. 7, 2015.
Application No. 14/846,987 is a continuation-in-part of application No. 15/080,427, filed on Mar. 24, 2016.
Application No. 15/080,427 is a continuation-in-part of application No. 15/605,920, filed on May 25, 2017.
Application No. 15/605,920 is a continuation-in-part of application No. 15/642,253, filed on Jul. 5, 2017.
Application No. 15/642,253 is a continuation-in-part of application No. 15/881,119, filed on Jan. 26, 2018.
Application No. 15/881,119 is a continuation-in-part of application No. 15/908,838, filed on Mar. 1, 2018.
Application No. 15/908,838 is a continuation-in-part of application No. 15/976,307, filed on May 10, 2018.
Application No. 14/846,987 is a continuation-in-part of application No. 14/621,332, filed on Feb. 12, 2015, now abandoned.
Application No. 15/080,427 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/642,253 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/881,119 is a continuation-in-part of application No. 15/605,920, filed on May 25, 2017.
Application No. 15/881,119 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/908,838 is a continuation-in-part of application No. 15/415,844, filed on Jan. 25, 2017.
Application No. 15/415,844 is a continuation-in-part of application No. 15/415,846, filed on Jan. 25, 2017.
Application No. 15/415,846 is a continuation-in-part of application No. 15/473,629, filed on Mar. 30, 2017.
Application No. 15/473,629 is a continuation-in-part of application No. 15/642,253, filed on Jul. 5, 2017.
Application No. 15/415,844 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/415,846 is a continuation-in-part of application No. 15/166,185, filed on May 26, 2016.
Application No. 15/353,537 is a continuation-in-part of application No. 15/289,126, filed on Oct. 8, 2016.
Application No. 15/415,846 is a continuation-in-part of application No. 15/289,126, filed on Oct. 8, 2016.
Application No. 15/289,126 is a continuation-in-part of application No. 15/353,537, filed on Nov. 16, 2016.
Application No. 15/473,629 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/353,537 is a continuation-in-part of application No. 15/415,844, filed on Jan. 25, 2017.
Application No. 15/415,844 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/473,629 is a continuation-in-part of application No. 15/415,844, filed on Jan. 25, 2017.
Application No. 15/415,844 is a continuation-in-part of application No. 15/415,846, filed on Jan. 25, 2017.
Application No. 15/415,846 is a continuation-in-part of application No. 15/462,536, filed on Mar. 17, 2017, now abandoned.
Application No. 15/289,126 is a continuation-in-part of application No. 15/166,185, filed on May 26, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
Application No. 15/462,536 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
(60) Provisional application No. 61/949,652, filed on Mar. 7, 2014.
(60) Provisional application No. 61/949,652, filed on Mar. 7, 2014.
(60) Provisional application No. 62/166,771, filed on May 27, 2015.
(60) Provisional application No. 62/166,771, filed on May 27, 2015.

(51) Int. Cl. H05K 13/00; H05K 13/04; H01L 21/56; H01L 21/48; H01L 23/498

(52) U.S. Cl. CPC H05K 13/00; H05K 13/0469; H01L 21/568; H01L 23/3121; H01L 23/49838; H01L 23/49822; H01L 21/4857

(57) ABSTRACT

A method of making an interconnect substrate mainly includes steps of: providing metal posts around a stress modulator, providing a molding compound to bind the stress modulator and the metal posts, providing a crack inhibiting layer on the stress modulator and the molding compound and interfaces between the stress modulator and the molding compound, and depositing metal conductors on the crack inhibiting layer and electrically connected to the metal posts. The metal conductors have interconnect pads superimposed over the stress modulator so that bumps for device connection can be mounted at the area covered by the stress modulator, thereby avoiding cracking of the bumps.

### CROSS REFERENCE TO RELATED APPLICATIONS

This application is a continuation-in-part of U.S. application Ser. No. 14/846,987 filed Sep. 7, 2015, a continuation-in-part of U.S. application Ser. No. 15/080,427 filed Mar. 24, 2016, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018.

The U.S. application Ser. No. 14/846,987 is a continuation-in-part of U.S. application Ser. No. 14/621,332 filed Feb. 12, 2015. The U.S. application Ser. No. 15/080,427 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/642,253 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/908,838 is a continuation-in-part of U.S. application Ser. No. 15/415,844 filed Jan. 25, 2017, a continuation-in-part of U.S. application Ser. No. 15/415,846 filed Jan. 25, 2017, a continuation-in-part of U.S. application Ser. No. 15/473,629 filed Mar. 30, 2017 and a continuation-in-part of U.S. application Ser. No. 15/642,253 filed Jul. 5, 2017. The U.S. application Ser. No. 15/976,307 is a division of pending U.S. patent application Ser. No. 14/621,332 filed Feb. 12, 2015.

The U.S. application Ser. No. 14/621,332 claims benefit of U.S. Provisional Application Ser. No. 61/949,652 filed Mar. 7, 2014. The U.S. application Ser. Nos. 15/415,844 and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, a continuation-in-part of U.S. application Ser. No. 15/289,126 filed Oct. 8, 2016, a continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. No. 15/462,536 is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The entirety of each of said applications is incorporated herein by reference.

### FIELD OF THE INVENTION

The present invention relates to methods of making an interconnect substrate and making a flip chip assembly using the same and, more particularly, to methods of making an interconnect substrate having a stress modulator therein and a crack inhibiting layer over the stress modulator and its surrounding materials and making a flip chip assembly having at least one bump superimposed over the stress modulator of interconnect substrate.

### DESCRIPTION OF RELATED ART

High performance microprocessors and ASICs require advanced packaging technologies such as flip chip assembly to address various performance needs. Flip chip assembly involves providing pre-formed bumps on the chip pads, flipping the chip so that the bumps face down and are aligned with and contact matching bond sites on the package substrate, and melting the solder on the bumps to wet the bond sites. After the solder reflows it is cooled down and solidified to form solder joints between the chip and the package substrate. Compared to the face-up chip mounting configurations, flip chip provides the shortest possible leads, the lowest inductance, the highest frequencies, the best noise control, the smallest device footprints, and the lowest profile.

While flip chip technology has tremendous advantages over wire bonding, its technical limitations are significant. For instance, solder bumps are vulnerable to stresses or strains induced by thermal expansion mismatch between the semiconductor chip and the package substrate. These bumps exhibit increased electrical resistance as well as cracks and voids over time due to fatigue from thermo-mechanical stresses.

U.S. Pat. No. 9,698,072 to Brofman et al., U.S. Pat. No. 9,583,368 to Hong and U.S. Pat. No. 9,287,143 to Chen et al. disclose flip chip assemblies in which a resin or a molding compound is placed between the chip and the substrate and acts as encapsulant of the solder bumps as well as a binder between the chip and the substrate. This underfill material mechanically locks the flip chip surface to the substrate, thereby reducing the strains imposed on the small bumps. The underfill consequently prevents the bumps from being damaged (e.g., cracking, severing) during thermal expansion of the package and the long-time reliability of underlined flip chip packages is enhanced compared to counterparts without an underfill. However, drawbacks to this approach include complicated manufacturing requirements, high cost, and unpredictable bump cracks if the underfill dispensing is defective.

U.S. Pat. No. 9,773,685 to Pendse et al. and U.S. Pat. No. 9,583,367 to Huang et al. disclose flip chip assemblies in which solder bumps are connected directly onto a lead (BOL), onto a trace (BOT) or onto a narrow pad (BONP) of the substrate in hope that higher reliability can be achieved. However, as the CTE of a laminate (organic) substrate is typically in a range about 16-18 ppm/degree C. and the CTE of silicon is about 2-3 ppm/degree C., the significant CTE mismatch makes these minor modifications inefficient.

In view of the various development stages and limitations in current flip chip assemblies, there is a need to fundamentally resolve the thermal mechanical stress induced on the bumps and in the interconnect substrate due to CTE mismatches in the assembly.

### SUMMARY OF THE INVENTION

A primary objective of the present invention is to provide an interconnect substrate for a flip chip assembly in which flip chip bumps can be disposed above a stress modulator in the interconnect substrate so as to alleviate solder cracking defects caused by chip/substrate CTE mismatch, thereby ensuring flip chip reliability.

Another objective of the present invention is to provide an interconnect substrate for a flip chip assembly in which a crack inhibiting layer is disposed over the stress modulator and laterally extends to the rest of the interconnect substrate so as to prevent interfacial cracking between the stress modulator and its surrounding materials. Further, as routing lines for bump connection are spaced from the stress modulator and its surrounding materials by the crack inhibiting layer, undesirable cracks formed around the stress modulator can be restrained from extending to routing lines so that the signal integrity of the flip chip assembly can be ensured.

In accordance with the foregoing and other objectives, the present invention provides a method of making an interconnect substrate, comprising steps of: providing a metal plate having a first array of metal posts and a supporting carrier, wherein the first array of metal posts contact and project from a top side of the supporting carrier; disposing a stress modulator at a pre-determined location that is laterally surrounded by the first array of metal posts, wherein the stress modulator has a coefficient of thermal expansion less than 10 ppm/° C.; disposing a molding compound on the top side of the supporting carrier, wherein the molding compound binds the stress modulator and fills spaces between the metal posts of the first array; disposing a first crack inhibiting layer that covers a top surface of the stress modulator and further extends laterally over interfaces between the stress modulator and the molding compound and covers a top surface of the molding compound and top sides of the first array of metal posts, wherein the first crack inhibiting layer contains a resin matrix and reinforcing fibers impregnated in the resin matrix and formed into a fiber-interlocking sheet; depositing a plurality of first metal conductors on a top surface of the first crack inhibiting layer, wherein the first metal conductors have interconnect pads superimposed over the top surface of the stress modulator and are electrically connected to the first array of metal posts through a plurality of metallized vias in the first crack inhibiting layer; and removing at least one selected portion of the supporting carrier of the metal plate to expose a bottom surface of the molding compound.

In another aspect, the present invention provides a method of making a semiconductor assembly, comprising steps of: providing the aforementioned interconnect substrate by the above-mentioned method; and disposing a semiconductor device over the interconnect substrate and electrically coupling the semiconductor device to the interconnect pads of the first metal conductors through a plurality of bumps, wherein the bumps of the semiconductor device are aligned with and covered by the stress modulator.

Unless specifically indicated or using the term “then” between steps, or steps necessarily occurring in a certain order, the sequence of the above-mentioned steps is not limited to that set forth above and may be changed or reordered according to desired design.

The method of making the interconnect substrate according to the present invention have numerous advantages. For instance, providing the interconnect pads for bump attachment over the stress modulator is particularly advantageous as the low CTE of the stress modulator can reduce warpage in the bump attachment area and CTE mismatch between the semiconductor device and the bump attachment area can be reduced so that cracking of the bumps in connection with the interconnect pads and the semiconductor device can be avoided. Disposing the first inhibiting layer on the stress modulator and the molding compound to cover interfaces between the stress modulator and the molding compound can resolve the problem that the interfaces render circuitry unreliable. As the first inhibiting layer contains the fiber-interlocking sheet, cracks generated at the interfaces between the stress modulator and the molding compound can be restrained from extending into the first crack inhibiting layer so as to ensure reliability of the first metal conductors on the first crack inhibiting layer. Providing metal posts around the stress modulator can offer vertical connecting channels between the two opposite sides of the interconnect substrate.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of a metal plate in accordance with the first embodiment of the present invention;

FIGS. 3 and 4 are cross-sectional and top perspective views, respectively, of the structure of FIGS. 1 and 2 further provided with a stress modulator in accordance with the first embodiment of the present invention;

FIG. 7 is a cross-sectional view of the structure of FIG. 5 further provided with a first inhibiting layer and a metal sheet in accordance with the first embodiment of the present invention;

FIGS. 8 and 9 are cross-sectional and top perspective views, respectively, of the structure of FIG. 7 further provided with via openings in accordance with the first embodiment of the present invention;

FIGS. 10 and 11 are cross-sectional and top perspective views, respectively, of the structure of FIGS. 8 and 9 further provided with first metal conductors in accordance with the first embodiment of the present invention;

FIGS. 12 and 13 are cross-sectional and bottom perspective views, respectively, of the structure of FIGS. 10 and 11 after selective removal of the bottom portion of the metal plate to finish the fabrication of an interconnect substrate in accordance with the first embodiment of the present invention;

FIG. 14 is a cross-sectional view of a semiconductor assembly having a semiconductor device electrically connected to the interconnect substrate of FIG. 12 in accordance with the first embodiment of the present invention;

FIG. 15 is a cross-sectional view of the semiconductor assembly of FIG. 14 further provided with an underfill in accordance with the first embodiment of the present invention;

FIG. 16 is a cross-sectional view of the semiconductor assembly of FIG. 15 further provided with solder balls in accordance with the first embodiment of the present invention;

FIG. 17 is a cross-sectional view of the structure of FIG. 12 further provided with a second crack inhibiting layer and via openings in accordance with the second embodiment of the present invention;

FIG. 18 is a cross-sectional view of the structure of FIG. 17 further provided with second metal conductors to finish the fabrication of an interconnect substrate in accordance with the second embodiment of the present invention;

FIG. 19 is a cross-sectional view of a semiconductor assembly having a semiconductor device electrically connected to the interconnect substrate of FIG. 18 in accordance with the second embodiment of the present invention;

FIG. 20 is a cross-sectional view of the structure of FIG. 5 further provided with primary metal conductors in accordance with the third embodiment of the present invention;

FIG. 21 is a cross-sectional view of the structure of FIG. 20 further provided with a first crack inhibiting layer and via openings in accordance with the third embodiment of the present invention;

FIG. 22 is a cross-sectional view of the structure of FIG. 21 further provided with first metal conductors in accordance with the third embodiment of the present invention;

FIG. 23 is a cross-sectional view of the structure of FIG. 22 after selective removal of the bottom portion of the metal plate in accordance with the third embodiment of the present invention;

FIG. 24 is a cross-sectional view of the structure of FIG. 22 further provided with a second crack inhibiting layer and second metal conductors to finish the fabrication of an interconnect substrate in accordance with the third embodiment of the present invention;

FIG. 25 is a cross-sectional view of a semiconductor assembly having a semiconductor device electrically connected to the interconnect substrate of FIG. 24 in accordance with the third embodiment of the present invention;

FIG. 26 is a cross-sectional view of the structure with a stress modulator inserted into an aperture of a metal plate in accordance with the fourth embodiment of the present invention;

FIG. 27 is a cross-sectional view of the structure of FIG. 26 further provided with a molding compound in accordance with the fourth embodiment of the present invention;

FIG. 28 is a cross-sectional view of the structure of FIG. 27 further provided with a first crack inhibiting layer and via openings in accordance with the fourth embodiment of the present invention;

FIG. 29 is a cross-sectional view of the structure of FIG. 28 further provided with first metal conductors in accordance with the fourth embodiment of the present invention;

FIG. 30 is a cross-sectional view of the structure of FIG. 29 after selective removal of the bottom portion of the metal plate in accordance with the fourth embodiment of the present invention;

FIG. 31 is a cross-sectional view of the structure of FIG. 30 further provided with a second crack inhibiting layer and second metal conductors to finish the fabrication of an interconnect substrate in accordance with the fourth embodiment of the present invention;

FIGS. 32 and 33 are cross-sectional and top perspective views, respectively, of the structure of FIG. 5 further provided with a first crack inhibiting layer and via openings in accordance with the fifth embodiment of the present invention;

FIG. 34 is a cross-sectional view of the structure of FIG. 33 further provided with first metal conductors in accordance with the fifth embodiment of the present invention;

FIG. 35 is a cross-sectional view of the structure of FIG. 34 after selective removal of the bottom portion of the metal plate to finish the fabrication of an interconnect substrate in accordance with the fifth embodiment of the present invention;

FIG. 36 is a cross-sectional view of the structure of FIG. 34 after entire removal of the bottom portion of the metal plate in accordance with the sixth embodiment of the present invention; and

FIG. 37 is a cross-sectional view of the structure of FIG. 36 further provided with a second crack inhibiting layer and second metal conductors to finish the fabrication of an interconnect substrate in accordance with the sixth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

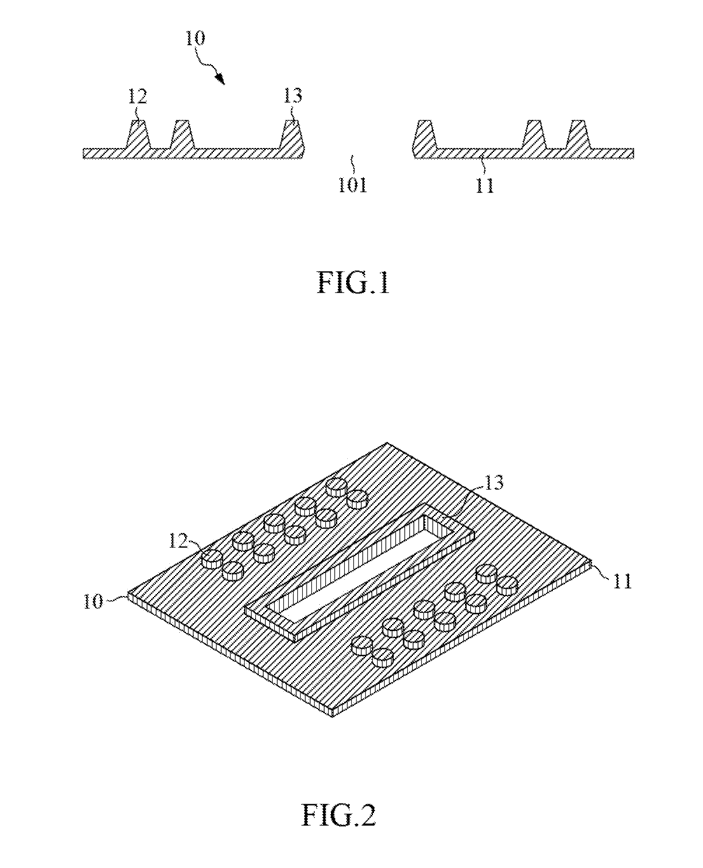

FIGS. 1-13 are schematic views showing a method of making an interconnect substrate that includes a first array of metal posts, a second array of metal posts, metal rings, a stress modulator, a molding compound, a first crack inhibiting layer and first metal conductors in accordance with the first embodiment of the present invention.

FIGS. 1 and 2 are cross-sectional and top perspective views, respectively, of a metal plate 10. The metal plate 10 typically is made of copper, aluminum, alloy 42, iron, nickel, silver, gold, combinations thereof, alloys thereof or any other suitable metals. In this embodiment, the metal plate 10 is made of copper and includes a supporting carrier 11, a first array of metal posts 12 and a metal ring 13. The first array of metal posts 12 and the metal ring 13 contact and project from a top side of the supporting carrier 11. The metal ring 13 laterally surrounds a pre-determined location for placement of a stress modulator, and the first array of metal posts 12 beyond the area enclosed by the metal ring 13 can serve as vertical transduction pathways. In this embodiment, as the metal posts 12 and the metal ring 13 are formed by a one-sided metal etching process, the metal posts 12 and the metal ring 13 can be shaped to have tapered sidewalls. As shown in FIG. 1, the lateral dimensions of the metal posts 12 and the metal ring 13 decrease as the metal posts 12 and the metal ring 13 extend away from the top side of the supporting carrier 11 in the upward direction. Additionally, the supporting carrier 11 is further etched from its bottom side to form an aperture 101 aligned with the pre-determined location enclosed by the metal ring 13.

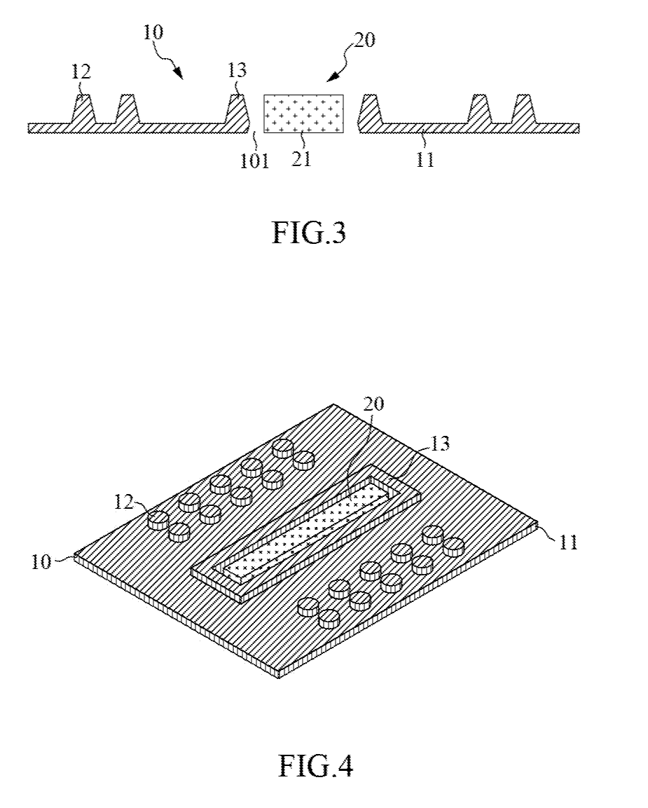

FIGS. 3 and 4 are cross-sectional and top perspective views, respectively, of the structure with a stress modulator 20 disposed at the pre-determined location surrounded by the metal ring 13. The stress modulator 20 has a low coefficient of thermal expansion (<10 ppm/° C.) and thus has a better matched CTE with silicon chip than that of the resin laminates. The material suitable for the stress modulator 20 includes ceramic, silicon, glass, composite materials, metal alloys and others. In this embodiment, the stress modulator 20 is a ceramic slug 21 and has a thickness substantially equal to the combined thickness of the supporting carrier 11 and the metal posts 12. The stress modulator 20 is placed within the metal ring 13 and inserted into the aperture 101 of the metal plate 10, with the top surface of the stress modulator 20 substantially coplanar with the top sides of the metal posts 12 and the metal ring 13 and the bottom surface of the stress modulator 20 substantially coplanar with the bottom side of the supporting carrier 11. In some cases, the interior sidewalls of the metal ring 13 may be used as an alignment guide to ensure the placement accuracy of the stress modulator 20. Accordingly, the stress modulator 20 can be accurately confined at the pre-determined location, with the peripheral edges of the stress modulator 20 in close proximity to the interior sidewalls of the metal ring 13.

FIGS. 5 and 6 are cross-sectional and top perspective views, respectively, of the structure provided with a molding compound 30. The molding compound 30 can be deposited on the top side of the supporting carrier 11 and fill into the remaining space within the metal ring 13 by paste printing, compressive molding, transfer molding, liquid injection molding, spin coating, or other suitable methods. As a result, the molding compound 30 laterally surrounds and conformally coats the metal posts 12, the metal ring 13 and the stress modulator 20 in lateral directions so as to bind peripheral edges of the stress modulator 20 and fill spaces between the metal posts 12. By planarization, the molding compound 30 has an exposed top surface substantially coplanar with the top sides of the metal posts 12 and the metal ring 13 and the top surface of the stress modulator 20, and an exposed bottom surface substantially coplanar with the bottom surface of the stress modulator 20.

The molding compound 30 mainly includes an organic resin binder and particulate inorganic fillers. In this embodiment, the organic resin binder has a coefficient of thermal expansion more than 20 ppm/° C., whereas the particulate inorganic fillers have a coefficient of thermal expansion less than 10 ppm/° C. Further, the content of the particulate inorganic fillers in the molding compound 30 preferably ranges from 30 to 90 weight percent based on the total weight of the molding compound 30. As a result, the CTE of the molding compound 30 can be adjusted to be more compatible to that of the metal plate 10 and the stress modulator 20 so as to reduce cracking or delamination caused by CTE mismatch.

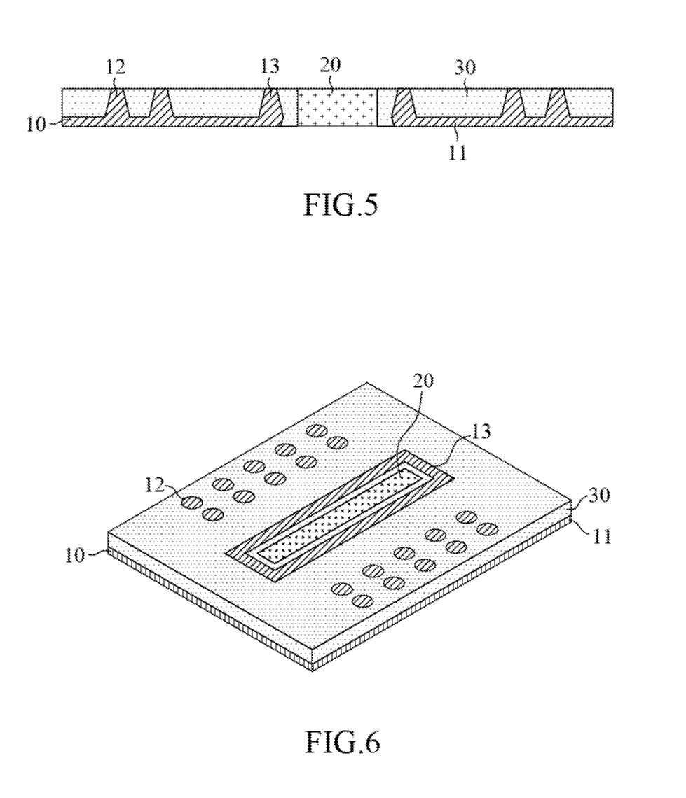

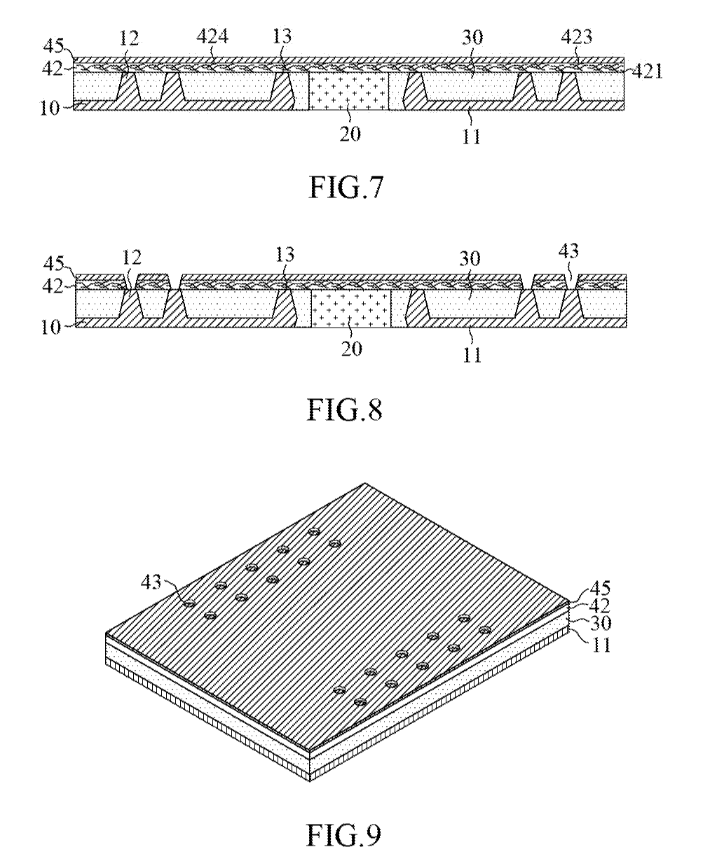

FIG. 7 is a cross-sectional view of the structure with a first crack inhibiting layer 42 and a metal sheet 45 laminated/coated on the stress modulator 20 and the molding compound 30 as well as the metal posts 12 and the metal ring 13 from above. The first crack inhibiting layer 42 contacts and is sandwiched between the stress modulator 20 and the metal sheet 45, between the molding compound 30 and the metal sheet 45, between the metal posts 12 and the metal sheet 45 and between the metal ring 13 and the metal sheet 45. In this embodiment, the first crack inhibiting layer 42 contains a resin matrix 421 and reinforcing fibers 423 impregnated in the resin matrix 421 and formed into a fiber-interlocking sheet 424. The reinforcing fibers 423 can be carbon fibers, silicon carbide fibers, glass fibers, nylon fibers, polyester fibers or polyamide fibers. Accordingly, even if cracks are generated at the interfaces between the stress modulator 20 and the molding compound 30 during thermal cycling, the interlocking structure of the reinforcing fibers 423 can restrain the cracks from extending into the first crack inhibiting layer 42 so as to ensure reliability of routing lines on the first crack inhibiting layer 42.

FIGS. 8 and 9 are cross-sectional and top perspective views, respectively, of the structure provided with via openings 43 to expose selected portions of the metal posts 12 from above. The via openings 43 are formed by numerous techniques including laser drilling, plasma etching and photolithography, and typically have a diameter of 50 microns. Laser drilling can be enhanced by a pulsed laser. Alternatively, a scanning laser beam with a metal mask can be used. The via openings 43 extend through the first crack inhibiting layer 42 and the metal sheet 45, and are aligned with selected portions of the metal posts 12.

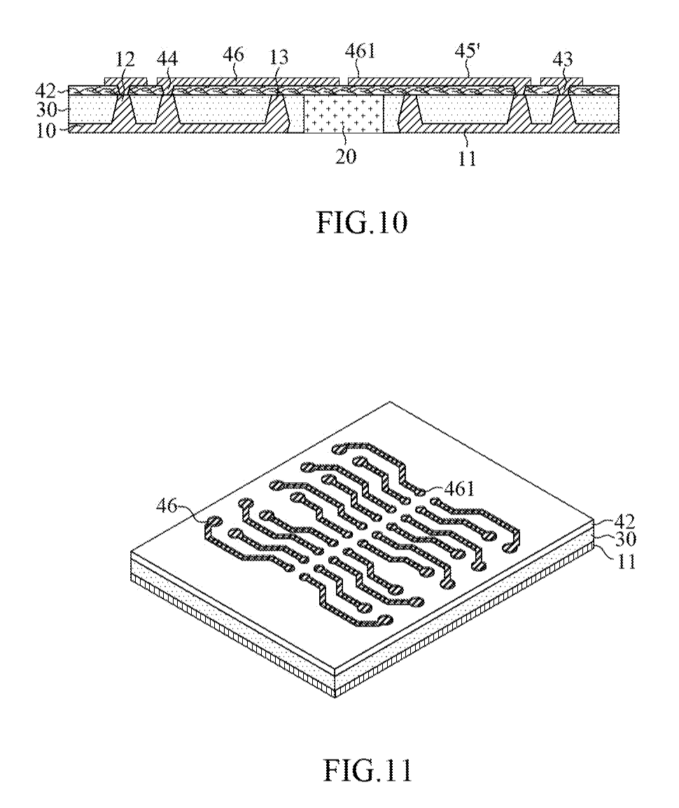

FIGS. 10 and 11 are cross-sectional and top perspective views, respectively, of the structure provided with first metal conductors 46 on the first crack inhibiting layer 42 from above by metal deposition and metal patterning process as mentioned below. A plated layer 45′ is deposited on the metal sheet 45 and into via openings 43, followed by patterning the metal sheet 45 as well as the plated layer 45′ thereon to form the first metal conductors 46. The first metal conductors 46 extend from the metal posts 12 in the upward direction, fill up the via openings 43 to form metallized vias 44 in direct contact with the metal posts 12, and extend laterally on the top surface of the first crack inhibiting layer 42. As a result, the first metal conductors 46 have interconnect pads 461 superimposed over the top surface of the stress modulator 20, and further extend laterally from the interconnect pads 461 towards the peripheral area to be electrically connected to the metal posts 12 through the metallized vias 44 in the first crack inhibiting layer 42.

The plated layer 45′ can be deposited by any of numerous techniques including electroplating, electroless plating, evaporating, sputtering, and their combinations, as a single layer or multiple layers. For instance, it can be deposited by first dipping the structure in an activator solution to render the structure catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer 45′ and the metal sheet 45 can be together patterned to form the first metal conductors 46 by any of numerous techniques including wet etching, electro-chemical etching, laser-assist etching, and their combinations, with an etch masks (not shown) thereon that define the first metal conductors 46.

The metal sheet 45 the plated layer 45′ are shown as a single layer for convenience of illustration. The boundary between the metal layers may be difficult or impossible to detect since copper is plated on copper. However, the boundaries between the plated layer 45′ and the first crack inhibiting layer 42 are clear.

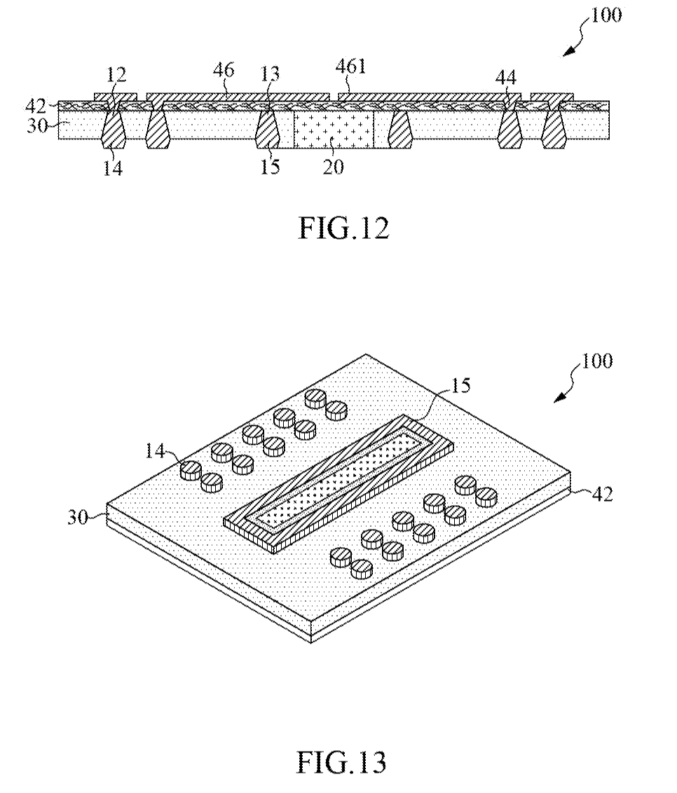

FIGS. 12 and 13 are cross-sectional and bottom perspective views, respectively, of the structure formed with a second array of metal posts 14 and a metal ring 15. The second array of metal posts 14 are aligned with the first array of metal posts 12, whereas the lower metal ring 15 is aligned with the upper metal ring 13. In this embodiment, as the second array of metal posts 14 and the lower metal ring 15 are formed by a one-sided metal etching process from the bottom side of the supporting carrier 11, the second array of metal posts 14 and the lower metal ring 15 can be shaped to have tapered sidewalls not covered by the molding compound 30. As shown in FIG. 12, the lateral dimensions of the metal posts 14 and the metal ring 15 decrease as the metal posts 14 and the metal ring 15 extend away from the bottom surface of the molding compound 30 in the downward direction.

Accordingly, an interconnect substrate 100 is accomplished and includes the first array of metal posts 12, the second array of metal posts 14, the metal rings 13, 15, the stress modulator 20, the molding compound 30, the first crack inhibiting layer 42 and the first metal conductors 46.

FIG. 14 is a cross-sectional view of a semiconductor assembly 110 with a semiconductor device 61 electrically connected to the interconnect substrate 100 illustrated in FIG. 12. The semiconductor device 61, illustrated as a chip, is face-down mounted on the interconnect pad 461 through bumps 71. As the low CTE of the stress modulator 20 can reduce CTE mismatch between the semiconductor device 61 and the bump attachment area covered by the stress modulator 20 from below and inhibit warpage in the bump attachment area during thermal cycling, the bumps 71 aligned with and completely covered by the stress modulator 20 from below will not suffer from cracking, thereby avoiding disconnection between the semiconductor device 61 and the interconnect substrate 100.

FIG. 15 is a cross-sectional view of the semiconductor assembly 110 of FIG. 14 further provided with an underfill 81. Optionally, the underfill 81 may be further provided to fill gaps between the semiconductor device 61 and the interconnect substrate 100.

FIG. 16 is a cross-sectional view of the semiconductor assembly 110 of FIG. 15 further provided with solder balls 91. Optionally, the solder balls 91 may be further mounted on the metal posts 14 for next-level connection.

### Embodiment 2

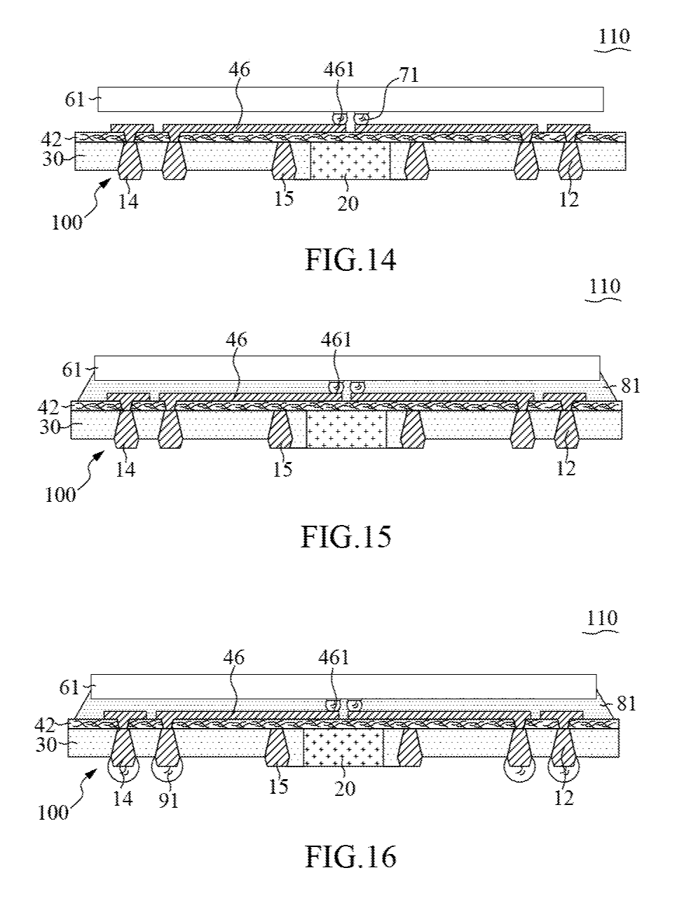

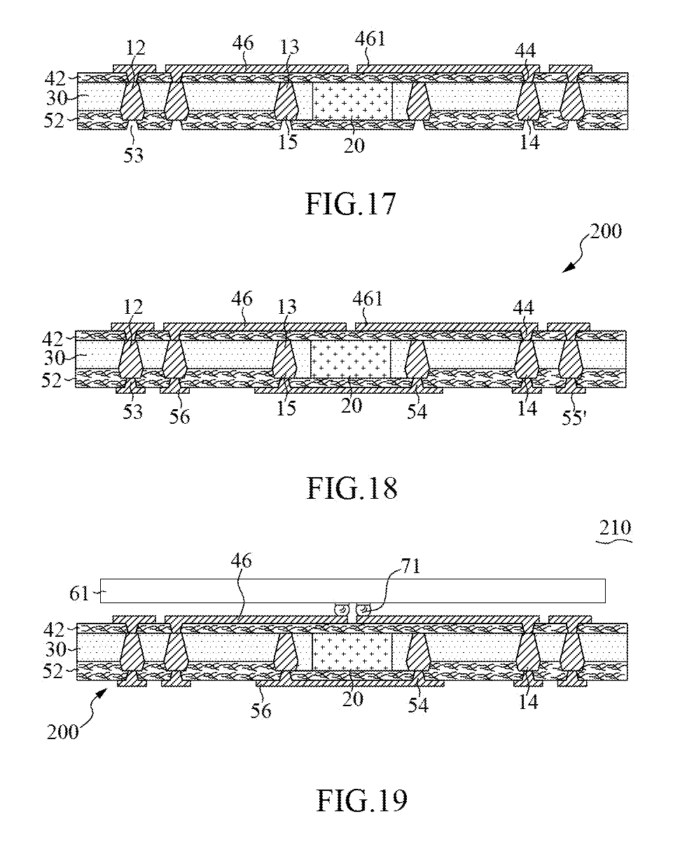

FIGS. 17-18 are schematic views showing a method of making an interconnect substrate with a second crack inhibiting layer and second metal conductors in accordance with the second embodiment of the present invention.

For purposes of brevity, any description in Embodiment 1 above is incorporated herein insofar as the same is applicable, and the same description need not be repeated.

FIG. 17 is a cross-sectional view of the structure of FIG. 12 further provided with a second crack inhibiting layer 52 and via openings 53 in the second crack inhibiting layer 52. The second crack inhibiting layer 52 covers and contacts the bottom surface of the stress modulator 20 and the bottom surface of the molding compound 30 as well as the bottom sides of the metal posts 14 and the metal ring 15 from below. The via openings 53 extend through the second crack inhibiting layer 52 to expose selected portions of the metal posts 14 and the metal ring 15 from below. In this embodiment, the second crack inhibiting layer 52 contains a resin matrix and reinforcing fibers impregnated in the resin matrix and formed into a fiber-interlocking sheet.

FIG. 18 is a cross-sectional view of the structure provided with second metal conductors 56 on the second crack inhibiting layer 52 from below by metal deposition and metal patterning process as mentioned below. A plated layer 55′ is deposited on the second crack inhibiting layer 52 and into via openings 53, followed by patterning the plated layer 55′ to form the second metal conductors 56. The second metal conductors 56 extend from the metal posts 14 and the metal ring 15 in the downward direction, fill up the via openings 53 to form metallized vias 54 in direct contact with the metal posts 14 and the metal ring 15, and extend laterally on the bottom surface of the second crack inhibiting layer 52. As a result, the second metal conductors 56 are electrically connected to the first metal conductors 46 through the metal posts 12, 14 and to the metal rings 13, 15 for ground connection.

Accordingly, an interconnect substrate 200 is accomplished and includes the first array of metal posts 12, the second array of metal posts 14, the metal rings 13, 15, the stress modulator 20, the molding compound 30, the first crack inhibiting layer 42, the first metal conductors 46, the second crack inhibiting layer 52 and the second metal conductors 56.

FIG. 19 is a cross-sectional view of a semiconductor assembly 210 with a semiconductor device 61 electrically connected to the interconnect substrate 200 illustrated in FIG. 18. The semiconductor device 61 is flip-chip electrically connected to the first metal conductors 46 through bumps 71 aligned with and covered by the stress modulator 20.

### Embodiment 3

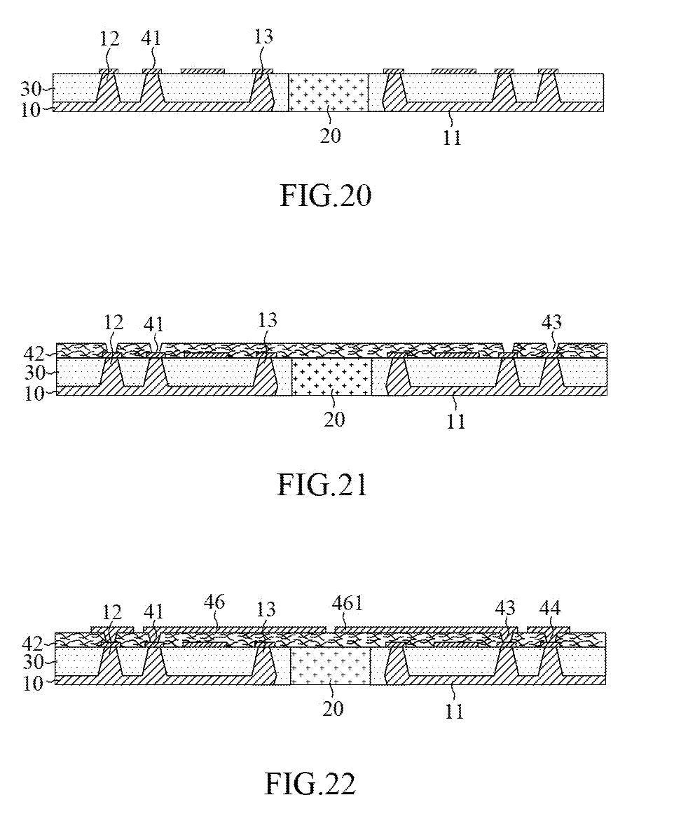

FIGS. 20-24 are schematic views showing a method of making an interconnect substrate with primary metal conductors on the molding compound in accordance with the third embodiment of the present invention.

For purposes of brevity, any description in the Embodiments above is incorporated herein insofar as the same is applicable, and the same description need not be repeated.

FIG. 20 is a cross-sectional view of the structure of FIG. 5 further provided with primary metal conductors 41 on the molding compound 30. The primary metal conductors 41 contact and extend laterally on the top surface of the molding compound 30 and are electrically connected to the first array of metal posts 12 and the metal ring 13.

FIG. 21 is a cross-sectional view of the structure with a first crack inhibiting layer 42 and via openings 43. The first crack inhibiting layer 42 covers the top surface of the stress modulator 20 and further extends laterally over interfaces between the stress modulator 20 and the molding compound 30 and covers the top surface of the molding compound 30 as well as the primary metal conductors 41. The via openings 43 extend through the first crack inhibiting layer 42 to expose selected portions of the primary metal conductors 41 from above.

FIG. 22 is a cross-sectional view of the structure provided with first metal conductors 46 on the first crack inhibiting layer 42 from above by metal deposition and metal patterning process. The first metal conductors 46 extend from the primary metal conductors 41 in the upward direction, fill up the via openings 43 to form metallized vias 44 in direct contact with the primary metal conductors 41, and extend laterally on the first crack inhibiting layer 42. As a result, the first metal conductors 46 are electrically connected to the metal posts 12 through the primary metal conductors 41.

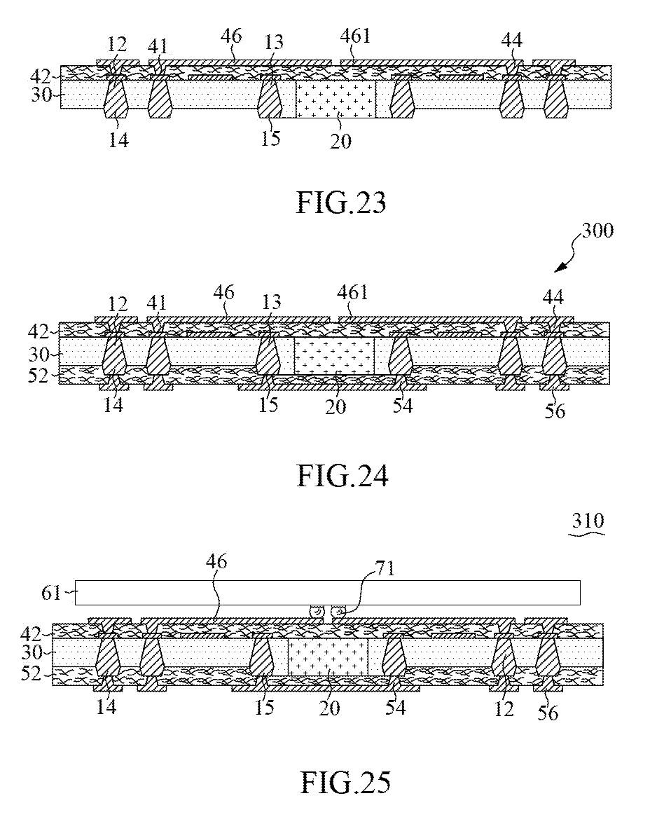

FIG. 23 is a cross-sectional view of the structure formed with a second array of metal posts 14 and a metal ring 15. The supporting carrier 11 is selectively removed to expose the bottom surface of the molding compound 30 from below and form the metal posts 14 and the metal ring 15. The second array of metal posts 14 contact and are aligned with the first array of metal posts 12, whereas the lower metal ring 15 contacts and is aligned with the upper metal ring 13.

FIG. 24 is a cross-sectional view of the structure provided with a second crack inhibiting layer 52 and second metal conductors 56. The second crack inhibiting layer 52 covers and contacts the bottom surface of the stress modulator 20 and the bottom surface of the molding compound 30 as well as the bottom sides of the metal posts 14 and the metal ring 15 from below. The second metal conductors 56 extend from the metal posts 14 and the metal ring 15 in the downward direction, fill up the via openings 53 to form metallized vias 54 in direct contact with the metal posts 14 and the metal ring 15, and extend laterally on the second crack inhibiting layer 52.

Accordingly, an interconnect substrate 300 is accomplished and includes the first array of metal posts 12, the second array of metal posts 14, the metal rings 13, 15, the stress modulator 20, the molding compound 30, the primary metal conductors 41, the first crack inhibiting layer 42, the first metal conductors 46, the second crack inhibiting layer 52 and the second metal conductors 56.

FIG. 25 is a cross-sectional view of a semiconductor assembly 310 with a semiconductor device 61 electrically connected to the interconnect substrate 300 illustrated in FIG. 24. The semiconductor device 61 is flip-chip electrically connected to the first metal conductors 46 through bumps 71 aligned with and covered by the stress modulator 20.

### Embodiment 4

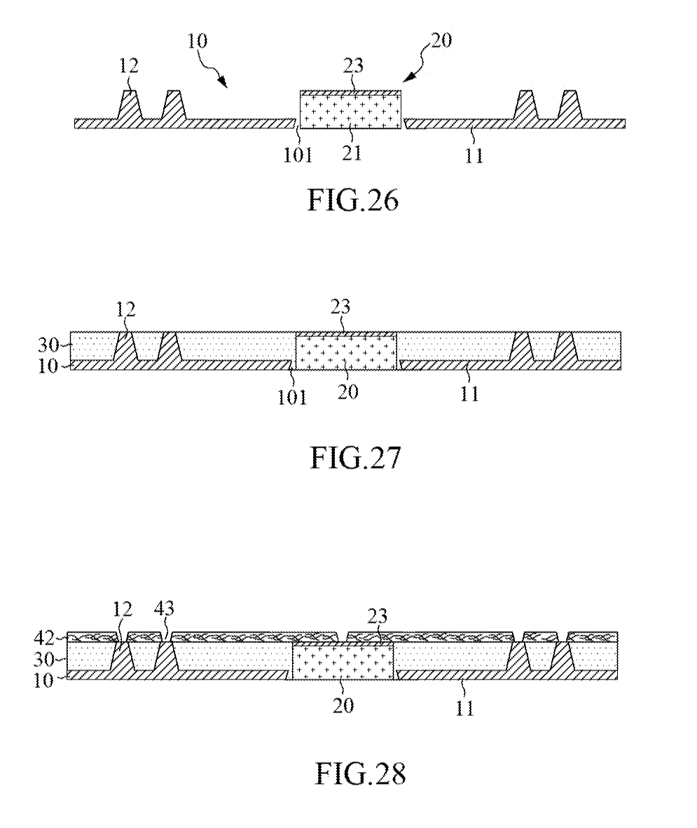

FIGS. 26-31 are schematic views showing a method of making an interconnect substrate with the first metal conductors grounded to the stress modulator in accordance with the fourth embodiment of the present invention.

For purposes of brevity, any description in the Embodiments above is incorporated herein insofar as the same is applicable, and the same description need not be repeated.

FIG. 26 is a cross-sectional view of the structure with a stress modulator 20 inserted into an aperture 101 of a metal plate 10. The metal plate 10 and the stress modulator 20 are similar to those illustrated in FIG. 3, except that the metal plate 10 includes no metal ring and the stress modulator 20 has a top metal layer 23 at the top surface thereof. In this embodiment, the interior sidewalls of the aperture 101 of the metal plate 10 can be used as an alignment guide to ensure the placement accuracy of the stress modulator 20. Accordingly, the stress modulator 20 can be accurately confined at the pre-determined location laterally surrounded by the metal posts 12, with the peripheral edges of the stress modulator 20 in close proximity to the interior sidewalls of the aperture 101 of the metal plate 10.

FIG. 27 is a cross-sectional view of the structure provided with a molding compound 30. The molding compound 30 covers the top surface of the supporting carrier 11 and sidewalls of the metal posts 12 and the stress modulator 20 and further fills into the space between peripheral edges of the stress modulator 20 and the interior sidewalls of the aperture 101 of the metal plate 10.

FIG. 28 is a cross-sectional view of the structure provided with a first crack inhibiting layer 42 and via openings 43 in the first crack inhibiting layer 42. The first crack inhibiting layer 42 covers and contacts the top metal layer 23 of the stress modulator 20, the molding compound 30 and the metal posts 12 from above. The via openings 43 extend through the first crack inhibiting layer 42, and are aligned with selected portions of the metal posts 12 and the top metal layer 23.

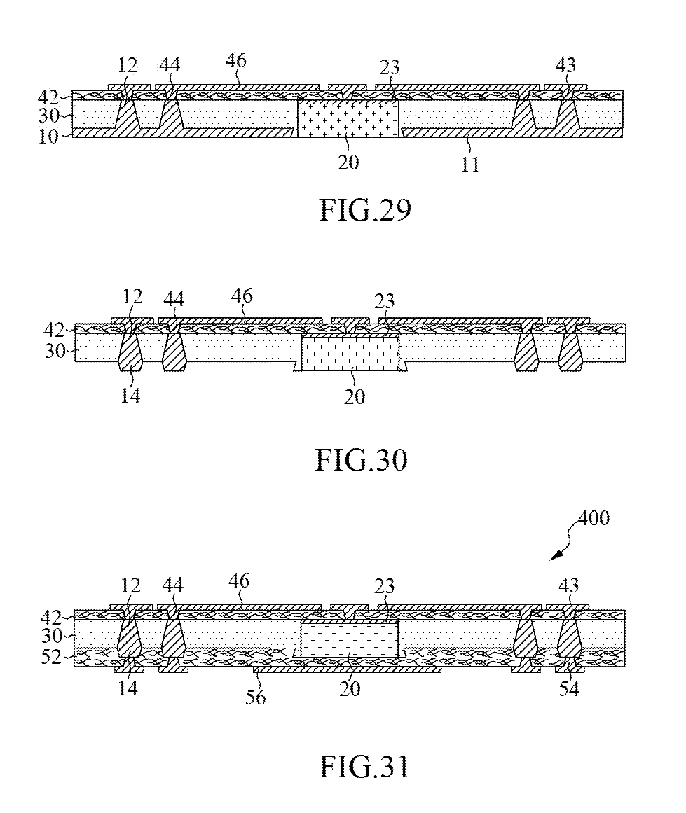

FIG. 29 is a cross-sectional view of the structure provided with first metal conductors 46 on the first crack inhibiting layer 42 from above by metal deposition and metal patterning process. The first metal conductors 46 extend from the metal posts 12 and the top metal layer 23 of the stress modulator 20 in the upward direction, fill up the via openings 43 to form metallized vias 44 in direct contact with the metal posts 12 and the top metal layer 23, and extend laterally on the first crack inhibiting layer 42. As a result, the first metal conductors 46 are electrically connected to the metal posts 12 for signal transduction and to the stress modulator 20 for ground connection.

FIG. 30 is a cross-sectional view of the structure formed with a second array of metal posts 14. The second array of metal posts 14 are aligned with the first array of metal posts 12 and electrically connected to the first metal conductors 46 through the first array of metal posts 12.

FIG. 31 is a cross-sectional view of the structure provided with a second crack inhibiting layer 52 and second metal conductors 56. The second crack inhibiting layer 52 covers and contacts the bottom surface of the stress modulator 20 and the bottom surface of the molding compound 30 as well as the bottom sides of the metal posts 14. The second metal conductors 56 extend from the metal posts 14 in the downward direction to form metallized vias 54 in the second crack inhibiting layer 52, and extend laterally on the second crack inhibiting layer 52.

Accordingly, an interconnect substrate 400 is accomplished and includes the first array of metal posts 12, the second array of metal posts 14, the stress modulator 20, the molding compound 30, the first crack inhibiting layer 42, the first metal conductors 46, the second crack inhibiting layer 52 and the second metal conductors 56.

### Embodiment 5

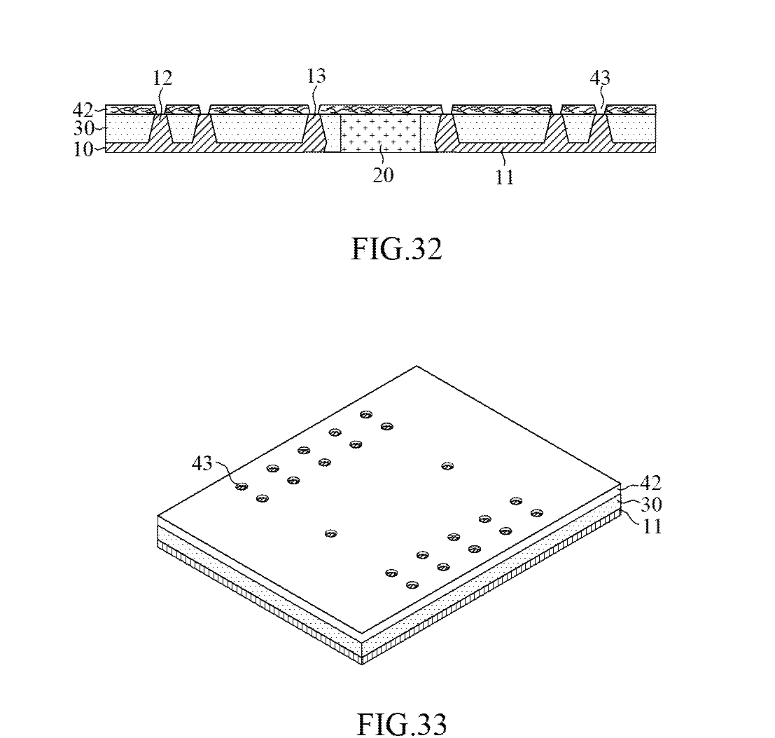

FIGS. 32-35 are schematic views showing a method of making an interconnect substrate with the first metal conductors grounded to the metal ring in accordance with the fifth embodiment of the present invention.

For purposes of brevity, any description in the Embodiments above is incorporated herein insofar as the same is applicable, and the same description need not be repeated.

FIGS. 32 and 33 are cross-sectional and top perspective views, respectively, of the structure of FIG. 5 further provided with a first crack inhibiting layer 42 and via openings 43. The first crack inhibiting layer 42 covers the metal posts 12, the metal ring 13, the stress modulator 20 and the molding compound 30 from above. The via openings 43 extend through the first crack inhibiting layer 42, and aligned with selected portions of the metal posts 12 and the metal ring 13.

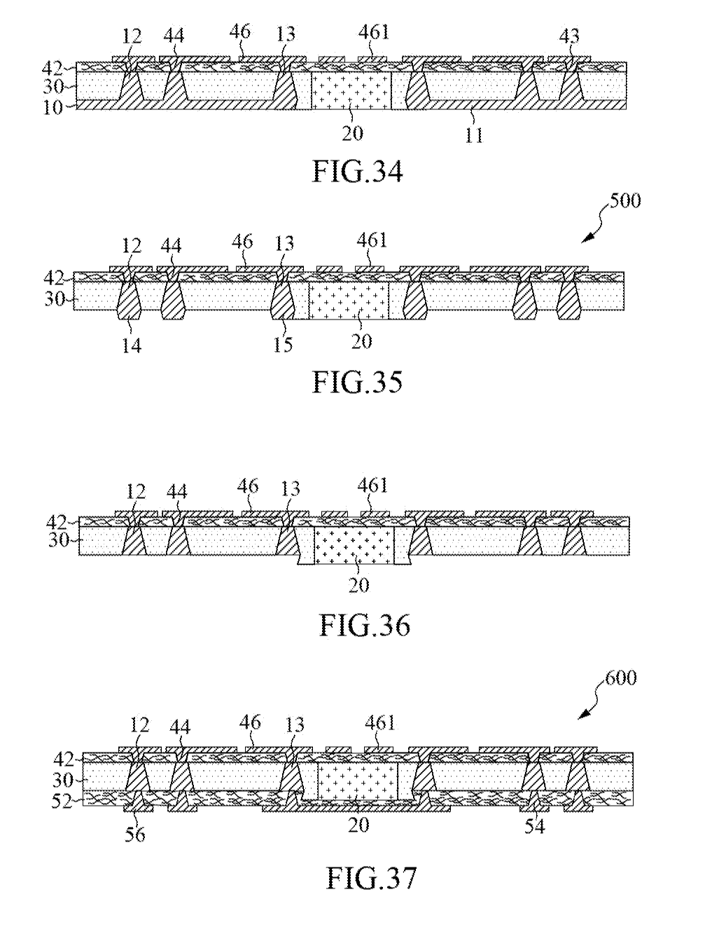

FIG. 34 is a cross-sectional view of the structure provided with first metal conductors 46 on the first crack inhibiting layer 42 from above by metal deposition and metal patterning process. The first metal conductors 46 extend from the metal posts 12 and the metal ring 13 in the upward direction, fill up the via openings 43 to form metallized vias 44 in direct contact with the metal posts 12 and the metal ring 13, and extend laterally on the first crack inhibiting layer 42. As a result, the first metal conductors 46 are electrically connected to the metal posts 12 for signal routing and to the metal ring 13 for ground connection.

FIG. 35 is a cross-sectional view of the structure formed with a second array of metal posts 14 and a metal ring 15. The supporting carrier 11 is selectively removed to form the metal posts 14 and the metal ring 15. The second array of metal posts 14 contact and are aligned with the first array of metal posts 12, whereas the lower metal ring 15 contacts and is aligned with the upper metal ring 13.

Accordingly, an interconnect substrate 500 is accomplished and includes the first array of metal posts 12, the second array of metal posts 14, the metal rings 13, 15, the stress modulator 20, the molding compound 30, the first crack inhibiting layer 42 and the first metal conductors 46.

### Embodiment 6

FIGS. 36-37 are schematic views showing a method of making an interconnect substrate without second array of metal posts combined with the first array of metal posts in accordance with the sixth embodiment of the present invention.

For purposes of brevity, any description in the Embodiments above is incorporated herein insofar as the same is applicable, and the same description need not be repeated.

FIG. 36 is a cross-sectional view of the structure of FIG. 34 after entire removal of the supporting carrier 11. By removing the supporting carrier 11 entirely, the bottom sides of the metal posts 12 and the metal ring 13 are exposed from below.

FIG. 37 is a cross-sectional view of the structure provided with a second crack inhibiting layer 52 and second metal conductors 56. The second crack inhibiting layer 52 covers and contacts the stress modulator 20 and the molding compound 30 as well as the metal posts 12 and the metal ring 13 from below. The second metal conductors 56 extend from the metal posts 12 and the metal ring 13 in the downward direction to form metallized vias 54 in the second crack inhibiting layer 52, and extend laterally on the second crack inhibiting layer 52. As a result, the second metal conductors 56 contact and are electrically connected to the metal posts 12 for signal transduction and to the metal ring 13 for ground connection.

Accordingly, an interconnect substrate 600 is accomplished and includes the metal posts 12, the metal ring 13, the stress modulator 20, the molding compound 30, the first crack inhibiting layer 42, the first metal conductors 46, the second crack inhibiting layer 52 and the second metal conductors 56.

As illustrated in the aforementioned embodiments, a distinctive interconnect substrate is configured to have interconnect pads superimposed over a stress modulator and exhibit improved reliability. In accordance with one preferred embodiment of the present invention, the interconnect substrate of the present invention includes: a stress modulator that has a coefficient of thermal expansion less than 10 ppm/° C.; a first array of metal posts that are disposed about and spaced from peripheral edges of the stress modulator; a molding compound that covers the peripheral edges of the stress modulator and sidewalls of the metal posts; a first crack inhibiting layer that covers a top surface of the stress modulator and further extends laterally over interfaces between the stress modulator and the molding compound and covers a top surface of the molding compound and top sides of the first array of metal posts; and first metal conductors laterally extend on a top surface of the first crack inhibiting layer, wherein the first metal conductors have interconnect pads superimposed over the top surface of the stress modulator and are electrically connected to the first array of metal posts through a plurality of metallized vias in the first crack inhibiting layer.

The stress modulator is a non-electronic component without signal connection thereto and typically has a coefficient of thermal expansion less than 10 ppm/° C. As the low CTE of the stress modulator can reduce CTE mismatch between the chip and the pad disposition area covered by the stress modulator and inhibit warpage in the pad disposition area during thermal cycling, cracking of conductive joints (such as bumps) aligned with and completely covered by the stress modulator can be avoided. Additionally, the stress modulator may have a top unpatterned metal layer electrically connected to at least one of the first metal conductors for ground connection through an additional metallized via in the first crack inhibiting layer.

The first array of metal posts laterally surround the stress modulator and can serve as vertical signal transduction pathways or provide ground/power plane for power delivery and return. As the first array of metal posts can be formed by a metal etching process, they may have tapered sidewalls. In a preferred embodiment, the height of the metal posts of the first array is less than the thickness of the stress modulator, and the lateral dimensions of the metal posts of the first array decrease as the metal posts of the first array extend from the bottom surface of the molding compound to the top surface of the molding compound.

The molding compound can provide mechanical bonds between the stress modulator and the first array of metal posts, and may have a larger thickness where it contacts sidewalls of the stress modulator than where it contacts sidewalls of the metal posts of the first array. By planarization, the molding compound can have a planar top surface substantially coplanar with the top surface of the stress modulator and the top sides of the metal posts of the first array. In a preferred embodiment, the molding compound mainly includes an organic resin binder and particulate inorganic fillers. As the particulate inorganic fillers can have a coefficient of thermal expansion less than 10 ppm/° C., the CTE of the molding compound can be adjusted to be more compatible to that of the metal posts and the stress modulator.

The first crack inhibiting layer can serve as an electrically insulating spacer and provide a reliable platform for circuitry deposition thereon. By interlocking of reinforcing fibers in the first crack inhibiting layer, the cracks generated at the interfaces between the stress modulator and the molding compound can be restrained from extending into the first crack inhibiting layer so as to ensure reliability of routing lines on the first crack inhibiting layer. The examples of the reinforcing fibers include carbon fibers, silicon carbide fibers, glass fibers, nylon fibers, polyester fibers and polyamide fibers.

The first metal conductors provide interconnect pads located over the top surface of the stress modulator and further extend laterally from the interconnect pads across the area over interfaces between the stress modulator and the molding compound to be electrically connected to the first array of metal posts. As the interconnect pads for device connection are superimposed over the top surface of the stress modulator, I/O disconnection between the interconnect pads and a semiconductor device flip-chip mounted on the interconnect pads can be avoided. Additionally, the first metal conductors may be further electrically connected to the top metal layer of the stress modulator and/or a metal ring around peripheral edges of the stress modulator through metallized vias in the first crack inhibiting layer for ground connection.

The interconnect substrate may further include a second array of metal posts in contact with the bottom sides of the first array of metal posts and projecting from the bottom surface of the molding compound. The combined height of the first metal posts and the second metal posts can be substantially equal to the thickness of the stress modulator. As the second array of metal posts can be formed by a metal etching process, they may have tapered sidewalls not covered by the molding compound. In a preferred embodiment, the bottom sides of the metal posts of the second array are substantially coplanar with the bottom surface of the stress modulator, and the lateral dimensions of the metal posts of the second array decrease as the metal posts of the second array extend away from the bottom surface of the molding compound and the bottom sides of the first array of metal posts.

For further routing, the interconnect substrate may further include a second crack inhibiting layer and second metal conductors on the second crack inhibiting layer. The second crack inhibiting layer covers the bottom surface of the molding compound and the bottom surface of the stress modulator to serve as an electrically insulating spacer and provide a reliable platform for circuitry deposition thereon. The second metal conductors extend laterally on the bottom surface of the second crack inhibiting layer and are electrically connected to the first metal conductors through the first array of metal posts and optionally the second array of metal posts. Additionally, the second metal conductors may further be electrically connected to the metal ring around the stress modulator for ground connection.

The present invention also provides a semiconductor assembly in which a semiconductor device such as chip is electrically connected to the interconnect pads of the aforementioned interconnect substrate through a plurality of bumps aligned with and covered by the stress modulator. Preferably, each of the bumps for device connection is entirely positioned within the area completely covered by the stress modulator and does not laterally extend beyond peripheral edges of the stress modulator.

The term “cover” refers to incomplete or complete coverage in a vertical and/or lateral direction. For instance, in a preferred embodiment, the stress modulator completely covers the bumps regardless of whether other elements such as the first crack inhibiting layer and the first metal conductors are between the stress modulator and the bumps.

The phrases “mounted on” include contact and non-contact with a single or multiple support element(s). For instance, in a preferred embodiment, the semiconductor device is mounted on the interconnect pads regardless of whether the semiconductor device is separated from the interconnect pads by the bumps.

The phrase “aligned with” refers to relative position between elements regardless of whether elements are spaced from or adjacent to one another or one element is inserted into and extends into the other element. For instance, in a preferred embodiment, the interior sidewalls of the aperture of the metal plate are laterally aligned with the peripheral edges of the stress modulator since an imaginary horizontal line intersects the interior sidewalls of the aperture of the metal plate and the peripheral edges of the stress modulator, regardless of whether another element is between the interior sidewalls of the aperture of the metal plate and the peripheral edges of the stress modulator and is intersected by the line, and regardless of whether another imaginary horizontal line intersects the peripheral edges of the stress modulator but not the interior sidewalls of the aperture of the metal plate or intersects the interior sidewalls of the aperture of the metal plate but not the peripheral edges of the stress modulator. Likewise, in a preferred embodiment, the bumps are aligned with the stress modulator since an imaginary vertical line intersects the bumps and the stress modulator, regardless of whether another element is between the bumps and the stress modulator and is intersected by the line, and regardless of whether another imaginary vertical line intersects the stress modulator but not the bumps or intersects the bumps but not the stress modulator.

The phrase “in close proximity to” refers to a gap between elements not being wider than the maximum acceptable limit. As known in the art, when the gap between the peripheral edges of the stress modulator and the interior sidewalls of the aperture of the metal plate or between the peripheral edges of the stress modulator and the interior sidewalls of the metal ring is not narrow enough, the stress modulator may not be accurately confined at a pre-determined location. The maximum acceptable limit for a gap between the peripheral edges of the stress modulator and the interior sidewalls of the aperture of the metal plate or between the peripheral edges of the stress modulator and the interior sidewalls of the metal ring can be determined depending on how accurately it is desired to dispose the stress modulator at the pre-determined location. Thereby, the descriptions “the peripheral edges of the stress modulator in close proximity to the interior sidewalls of the metal ring” and “the peripheral edges of the stress modulator in close proximity to the interior sidewalls of the aperture of the metal plate” mean that the gap between the peripheral edges of the stress modulator and the interior sidewalls of the aperture of the metal plate or between the peripheral edges of the stress modulator and the interior sidewalls of the metal ring is narrow enough to prevent the location error of the stress modulator from exceeding the maximum acceptable error limit.

The phrase “electrically connected” refer to direct and indirect electrical connection. For instance, in a preferred embodiment, the second array of metal posts are electrically connected to the first metal conductors by the first array of metal posts but are spaced from and do not contact the first metal conductors.

The interconnect substrate made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making an interconnect substrate, comprising steps of:
providing a metal plate having a first array of metal posts and a supporting carrier, wherein the first array of metal posts contact and project from a top side of the supporting carrier;
disposing a stress modulator at a pre-determined location that is laterally surrounded by the first array of metal posts, wherein the stress modulator has a coefficient of thermal expansion less than 10 ppm/° C.;
disposing a molding compound on the top side of the supporting carrier, wherein the molding compound binds the stress modulator and fills spaces between the metal posts of the first array;
disposing a first crack inhibiting layer that covers a top surface of the stress modulator and further extends laterally over interfaces between the stress modulator and the molding compound and covers a top surface of the molding compound and top sides of the first array of metal posts, wherein the first crack inhibiting layer contains a resin matrix and reinforcing fibers impregnated in the resin matrix and formed into a fiber-interlocking sheet;
depositing a plurality of first metal conductors on a top surface of the first crack inhibiting layer, wherein the first metal conductors have interconnect pads superimposed over the top surface of the stress modulator and are electrically connected to the first array of metal posts through a plurality of metallized vias in the first crack inhibiting layer; and
removing at least one selected portion of the supporting carrier of the metal plate to expose a bottom surface of the molding compound.

2. The method of claim 1, wherein the step of disposing the stress modulator at the pre-determined location includes disposing the stress modulator into an aperture of the metal plate, and the molding compound further fills into a space between peripheral edges of the stress modulator and interior sidewalls of the aperture of the metal plate.

3. The method of claim 1, wherein the reinforcing fibers of the first crack inhibiting layer include carbon fibers, silicon carbide fibers, glass fibers, nylon fibers, polyester fibers or polyamide fibers.

4. The method of claim 1, wherein the step of removing at least one selected portion of the supporting carrier of the metal plate is to remove the supporting carrier entirely.

5. The method of claim 1, wherein the step of removing at least one selected portion of the supporting carrier of the metal plate includes leaving remaining portions of the supporting carrier to form a second array of metal posts, and each of the metal posts of the second array is aligned with a respective one of the metal posts of the first array and electrically connected to at least one of the first metal conductors.

6. The method of claim 1, wherein the stress modulator has a top metal layer at the top surface thereof, and is further electrically connected to at least one of the first metal conductors through an additional metallized via in the first crack inhibiting layer.

7. The method of claim 1, wherein the first array of metal posts are formed by a metal etching process, and each of the metal posts of the first array has tapered sidewalls, and lateral dimensions of the metal posts of the first array decrease as the metal posts of the first array extend away from the top side of the supporting carrier.

8. The method of claim 5, wherein each of the metal posts of the second array has tapered sidewalls, and lateral dimensions of the metal posts of the second array decrease as the metal posts of the second array extend away from the bottom surface of the molding compound.

9. The method of claim 1, further comprising steps of:
forming a second crack inhibiting layer that covers the bottom surface of the molding compound and a bottom surface of the stress modulator; and
depositing a plurality of second metal conductors on a bottom surface of the second crack inhibiting layer, wherein the second metal conductors are electrically connected to the first metal conductors through the first array of metal posts.

10. The method of claim 1, wherein the metal plate further has a metal ring that contacts and projects from the top side of the supporting carrier and encloses the pre-determined location, and the step of disposing the stress modulator at the pre-determined location includes disposing the stress modulator within the metal ring.

11. The method of claim 10, wherein the metal ring is further electrically connected to at least one of the first metal conductors through an additional metallized via in the first crack inhibiting layer.

12. A method of making a semiconductor assembly, comprising steps of:
providing an interconnect substrate by the method of claim 1; and
disposing a semiconductor device over the interconnect substrate and electrically coupling the semiconductor device to the interconnect pads of the first metal conductors through a plurality of bumps, wherein the bumps of the semiconductor device are aligned with and covered by the stress modulator.
